(19) United States
(12) Patent Application Publication
(10) Pub. No.: US 2025/0056731 A1
(43) Pub. Date: Feb. 13, 2025

(54) DEVICE AND METHOD FOR MANUFACTURING PRINTED CIRCUIT BOARDS FOR ELECTRICAL AND/OR ELECTRONIC CIRCUITS

(71) Applicant: Jan Franck, Weidenberg (DE)

(72) Inventor: Jan Franck, Weidenberg (DE)

(21) Appl. No.: 18/928,399

(22) Filed: Oct. 28, 2024

Related U.S. Application Data
(63) Continuation-in-part of application No. 17/167,309, filed on Feb. 4, 2021.
Application No. 17/167,309 is a continuation-in-part of application No. 15/564,359, filed on Oct. 4, 2017, now abandoned.

(30) Foreign Application Priority Data
Apr. 13, 2015 (DE) 10 2015 004 508.3

(51) Int. Cl. H05K 3/12; B22F 10/22; B23K 26/342

(52) U.S. Cl. CPC H05K 3/1241; B22F 10/22; B23K 26/342; H05K 2203/1105

(57) ABSTRACT

A method for manufacturing printed circuit boards for electrical and electronic circuits, comprising an electrically nonconductive substrate (4) and electrically conductive tracks applied thereon, wherein the electrically conductive tracks are imprinted on the substrate (4), according to a desired conductor track layout, under the influence of heat applied to an electrically conductive printing medium (3), wherein the printing medium (3) comprises an electrically conductive metal or metal alloy having a melting temperature, and wherein the metal or metal alloy is configured to be selectively heated by a print head (2) at selected printing spots or pixels, wherein a conductive ingredient of the metal or metal alloy of the printing medium (3) is locally heated at least up to the melting temperature of the metal or the metal alloy, which is the melting point of the metal or metal alloy in the form of a bulk material and is melted thereby, and thereafter solidifys on the substrate (4) in the form of a common matrix, and wherein the printing medium (3) is situated on a side of-a film-like carrier (6), which side of the film-like carrier (6) faces the substrate (4), characterized in that the film-like carrier (6) is a carbon foil or a glass film, and is wound from a supply spool (7), along the substrate (4) to be imprinted, onto a laydown spool (8), and wherein, at least in a section of the carrier film (6) which is actually in the area of the print head (2), the side of the carrier film (6) bearing the printing medium (3) is always oriented parallel to the substrate (4) and rests flatly against the substrate (4), so that the metal or metal alloy is in direct contact with the substrate (4), and, after being melted by the print head (2) into its fluid aggregate state, the metal or metal alloy immediately moistens the substrate (4) and finally solidifies on the substrate (4) as a common matrix.

### REFERENCE TO PENDING PRIOR PATENT APPLICATIONS

This patent application:
(i) is a continuation-in-part of pending prior U.S. patent application Ser. No. 17/167,309, filed Feb. 4, 2021 by Jan Franck for DEVICE AND METHOD FOR MANUFACTURING PRINTED CIRCUIT BOARDS FOR ELECTRICAL AND/OR ELECTRONIC CIRCUITS (Attorney's Docket No.: KUCH-89 CIP), which patent application, in turn:
   (a) is a continuation-in-part of prior U.S. patent application Ser. No. 15/564,359, filed Oct. 4, 2017 by Jan Franck for DEVICE AND METHOD FOR PRODUCING PRINTED CIRCUIT BOARDS FOR ELECTRICAL AND/OR ELECTRONIC CIRCUITS (Attorney's Docket No.: KUCH-89), which patent application, in turn:
      (1) is a 371 national stage entry of prior International (PCT) Patent Application No. PCT/IB2016/000465, filed Apr. 13, 2016 by Jan Franck for DEVICE AND METHOD FOR PRODUCING PRINTED CIRCUIT BOARDS FOR ELECTRICAL AND/OR ELECTRONIC CIRCUITS, which patent application, in turn, claims benefit of German Patent Application No. DE 10 2015 004 508.3, filed Apr. 13, 2015.

The four (4) above-identified patent applications are hereby incorporated herein by reference.

### FIELD OF THE INVENTION

The invention is directed to (i) a method for manufacturing printed circuit boards for electrical and electronic circuits, comprising an electrically nonconductive substrate and electrically conductive tracks of homogenous thickness applied thereon, wherein the electrically conductive tracks are made of a material with a melting temperature higher than the melting temperature of soldering tin so that they will withstand the soldering of electronic components thereon by soldering tin without melting, and (ii) a device for manufacturing printed circuit boards for electrical and electronic circuits, comprising an electrically nonconductive substrate and electrically conductive tracks of homogenous thickness applied thereon, wherein the electrically conductive tracks are made of a material with a melting temperature higher than the melting temperature of soldering tin so that they will withstand the soldering of electronic components thereon by soldering tin without melting.

### BACKGROUND OF THE INVENTION

Printed circuit boards for electronic circuits are typically manufactured from a copper-coated substrate by etching away the copper after the desired conductor tracks have been transferred to the copper layer and have thus been selectively sealed, so that the copper beneath the sealed areas of the copper is not removed. However, this method is comparatively time-consuming, since the etching operation proceeds at only a limited speed.

The manufacturing of printed circuit boards for electrical and electronic circuits with electrically conductive tracks of homogenous thickness applied on a nonconductive substrate is entirely different to the soldering of electronic components by soldering tin onto such electrically conductive tracks. Apparatuses fo such a soldering of electronic components onto electrically conductive tracks are, for example, disclosed in the documents U.S. Pat. No. 236,972 A titled “Soldering Iron”, US 2013/0168370 A1 titled “Laser-Beam Device, Laser-Soldering Tool and Method for Laser-Soldering Connection Pads of a Head-Stack Assembly for a Hard-Disc Drive”, WO 2014/185543 A1 titled “Apparatus for Mounting Electronic Components” as well as in a film of a Laser-Soldering Process which can be watched at the internet address https://www.youtube.com/watch?v=KnyB9btlhS8. First of all, the soldering of components cannot be achieved on an electrically nonconductive substrate, but makes only sense at the electrically conductive tracks applied on the substrate of a printed circuit board, because an electrically nonconductive substrate cannot provide electrical conducts for the soldered components. On the other hand, tracks on printed circuit boards for electronic components shall have a momgenous thickness as they are the basis for the mounting of the electronic components. Finally, electrically conductive tracks applied on the substrate of a printed circuit board must have a rather higher melting temperature than soldering tin so that electronic components can be soldered thereon without impairing the structural integrity of the electrically conductive tracks. Therefore, the above mentioned documents cannot provide neither a method nor a device for the manufacturing of printed circuit boards for electrical and electronic circuits with electrically conductive tracks of homogenous thickness applied on a nonconductive substrate. Another aspect is that most soldering devices are controlled in such a way that the temperature applied to the soldering tin is only slightly above the melting temperature of soldering tin in order to protect the electronic components which are soldered onto a printed circuit board against overheating which could cause destruction of the electronic components. For this reason, such known soldering equipment for melting soldering tin cannot be used to heat metals which are used for the manufacturing of electrically conducting tracks up to a regarding melting temperature.

Furthermore, US 2011/0096388 A1 discloses flexible electro-optic devices for application onto a substrate, but the conducting tracks of a layout of a printed circuit do not consist of electro-optic devices.

Finally, according to US 2005/0005820 A1, an ink comprises a complex consisting of palladium chemically bound with an aliphatic amine in an palladium aliphatic amine complex, and this substance is solved in a liquid vehicle. Although palladium is a metal, it is part of an organic substance and therefore, it does not consist of metal particles but only of an organic substance solved in a liquid. Most organic substances have rather poor melting points compared to metals, and therefore, the structural integrity upon soldering of electronic components thereon is not ensured, especially as the thickness of the tracks applied in this way is only between 0.2 micrometers and 3 micrometers.

U.S. Pat. No. 4,590,482 titled “Nozzle Test Apparatus and Method for Thermal Ink Jet Systems” discloses only a special test mode for a conventional ink jet printer which has to be conducted with a conducting ink in order to find out whether some ink nozzles are clogged. In such modus, the conducting ink is sprayed onto an electrode plate, and in the moment of the ink leaving the nozzle, it can get in contact with the nozzle on the one hand and the electrode plate on the other hand, and an electric circuit is closed which can be surveyed to determine whether ink has been sprayed or not. By this conductive ink, no tracks of a layout of a printed circuit board can be generated, as the conducting ink has to be sprayed onto an electrically conductive electrode instead onto an electrically nonconducting substrate for the manufacture of a printed circuit board.

US 2018/0323139 A1 refers to methods for manufacturing a device with an integrated-circuit chip. There are two techniques disclosed in this document. One is called Fine Powder Coating (FPC). According to this technique, a plasma jet is generated which is directed from a fine-powder metal microparticle feeding inlet towards a substrate and transports the fine-powder metal microparticles onto the substrate. In this FPC method, there is no film-like carrier coated with a electrically conductive metal or metal alloy. The other technique disclosed in this document is called Laser Induced Forward Transfer (LIFT). According to this technique, a donor metal substrate is supported by a thin film and a transparent glass medium. Then, a laser beam pulse is produced in order to expel a portion of the donor material supported by the film through laser evaporation. On the other hand, by evaporation, the metal is converted into its gaseous phase and is not liquid anymore. In the gaseous state, the donor material cannot be delimited to a small area, but will form a cloud which precipitates in a rather wide area.

The document US 2015/0374920 A1 refers to a method for for a subcutaneous supply of a drug under the skin of a patient by use of a laser beam and not to a method for manufacturing printed circuit boards for electrical and electronic circuits.

On the other hand, according to the invention, there is no ink jet printer used to generate such conducting tracks of a layout of a printed circuit board, but a thermal printer where the material to be printed is placed on one side of a carrier foil which is transported in parallel to the transport of the substrate, and while both are in contact with each other, some spots of the foil with the material to be printed are heated and thereby are transferred onto the substrate.

The disadvantages of the described prior art have led to the underlying object of the invention, to refine a method and a device for manufacturing conductor tracks for electrical and/or electronic circuits in such a way that the manufacture is preferably rapid and can take place without extended processing times, and shows an optimum edge sharpness.

### SUMMARY OF THE INVENTION

For a generic method, this object is achieved in that a print medium comprising the material of the electrically conductive tracks is provided as a two-dimensional layer above the electrically nonconductive substrata and is transferred to, i.e., imprinted on, the electrically nonconductive substrate according to the desired conductor track layout, under the influence of heat selectively applied by a print head onto the printing medium, whereby the printing medium is transferred onto the substrate by selectively melting or sintering the material for the electrically conductive tracks, wherein the print head does not come into direct contact with the printing medium, since at least a foil-shaped carrier material carrying the two-dimensional layer of the printing medium is situated between the print head and the two-dimensional layer of the printing medium, wherein, at least in a section of the carrier film which is actually in the area of the print head, the side of the carrier film bearing the printing medium is always oriented parallel to the substrate and rests flatly against the substrate, so that the metal or metal alloy is in direct contact with the substrate, and, after being melted by the print head into its fluid aggregate state, the metal or metal alloy immediately moistens the substrate and finally solidifies on the substrate as a common matrix.

The invention does not start from a substrate coated with copper on the conductor track side, as in the prior art, but, rather, starts from a bare, electrically nonconductive substrate. The pattern of the conductor tracks is selectively imprinted thereon according to the desired conductor track layout. An electrically conductive printing medium, for example a compound containing silver, is used. However, this compound or this printing medium is not pressed by a print head or applied by means of a doctor blade or the like; instead, carrier material which is spread over the substrate to be imprinted is situated in a planarly distributed state on a film or the like. By selectively heating individual parts of the planarly distributed printing compound, the latter is then transferred to the substrate situated directly underneath or adjacently, where the printing compound resolidifies precisely in the desired pattern. A print head is hereby used that is provided only with individual, approximately punctiform heating elements that are preferably adjacently arranged in a row. The print head does not come into direct contact with the compound to be printed, since the carrier material having the printing compound is still situated in between. For this reason, large quantities of printed circuit boards may be imprinted without the print head becoming worn or only soiled.

In addition or as an alternative to silver as the electrically conductive component of the printing medium, other materials may be used, in particular metals such as aluminum, which has good electrical conductivity with a moderate melting point, as well as zinc or tin. All of these metals have melting points far below 1000° C., and may therefore be more easily heated to their melting point than silver, for example. The electrically conductive material could be applied to the carrier film in the form of nanoparticles. However, it is preferred according to the invention to apply the metal in question to the carrier film by vapor deposition. Of course, this is also possible with higher-melting materials such as silver or copper. For protection from oxidation, base, vapor-deposited metals may be sealed by a cover film which covers the metal, vapor-deposited on the carrier film, on the side of the metal that is initially still free.

All metals and metal alloys, for example those substances having a melting point of 1800° C. or lower, preferably having a melting point of 1500° C. or lower, more preferably having a melting point of 1200° C. or lower, in particular having a melting point of 1000° C. or lower, are also usable in principle as an electrically conductive component in the printing medium.

This electrically conductive material may be incorporated as a component in the printing medium, which then contains additional, preferably lower-melting, components such as binders, plasticizers, etc. However, it is also conceivable to apply such an electrically conductive substance in pure form to a film-like carrier substrate by vapor deposition, or to affix same adhesively, in particular in the form of nanoparticles, and to optionally cover with a further film that melts at a lower temperature than the nanoparticles.

However, the material in question should also be meltable by a print head at specific points. The lower the melting point of the material in question, the more easily this procedure may be carried out. In this regard, aluminum, having a melting point of 660° C. and an electrical conductivity of 35 m/ohm*mm², represents a good compromise. Zinc has a melting point of only 419° C. with an electrical conductivity of 16.9 m/ohm*mm²; for tin, the melting point is just 232° C., and the electrical conductivity is still 8.7 m/ohm*mm².

While conventional thermal print heads may thus be used for tin or zinc, for metals having higher melting points, such as aluminum or silver, hotter, specialized thermal print heads should be used. Instead of using heating resistors for generating localized heat spots, it would also be conceivable to use laser beams, for example, which are directed onto the individual print spots by means of optical aids such as optical fibers in a print head. Laser beams may also be switched on and off very quickly, and may be focused very precisely on individual spots, so that the energy density that is necessary for higher melting points may be generated with very little effort.

Heating the electrically conductive printing medium by means of a thermal print head has the advantage of a very sharp contrast, so that conductor tracks having extremely sharp edges may be reliably produced. In contrast to “cold” printing methods such as inkjet printers, for example, the individual metal particles are fused to form a combined matrix, and in fact form a uniform conductor without transfer resistances, whereas for strictly imprinting with nanoparticles, the overall conductivity is still dependent on the transfer resistances at the contact points, and in particular on whether there are even enough contact points at all.

Therefore, according to the present invention, the metal or metal alloy is only heated to or slightly above the melting temperature of the regarding metal or the metal alloy, which is the melting point of the metal or metal alloy in the form of a bulk material, for example in the form of a metal ingot. This is the standardized melting temperature without the influence of surface effects as they are relevant at the size of microparticles, for example.

On the other side, the metal or metal alloy is not heated to the boiling temperature or vaporization point of the regarding metal or metal alloy. Thereby, the metal or metal alloy is in its liquid state and can be precisely transferred to a narrow area of the substrate.

On the other hand, within the scope of the invention there is also the option for operating at a temperature below the melting temperature and only sintering the individual metal particles together, i.e., fusing them at the surface, until they flow together at a specific point. For this purpose, temperatures that are 10 to 20% below the melting point of the material in question, i.e., only 528° C. to 594° C. for aluminum, for example, are usually sufficient. It may also be sufficient to design the thermal print head only for temperatures between 80% and 90% of the melting temperature.

To further relieve the print head, it may be provided that the substrate to be imprinted is preheated to a temperature just below the required temperature, i.e., the melting temperature or the sintering temperature, so that the print head itself only has to overcome the remaining temperature difference. The most reliable approach is for the preheat temperature to be below the sintering temperature, so that in no event does undesirable sintering start to occur prior to the actual printing operation. The task of the thermal print head is then to locally heat the metal layer, which has been preheated to a temperature just below the sintering temperature (i.e., to 70% of the melting temperature, for example), to above the melting temperature, for example to 110% of the melting temperature. This difference is then in the range of approximately 40% of the melting temperature. In such cases, silver, having a typical melting point of 960° C., could also be processed with a print head whose heating capacity is only approximately 384° C. to 400° C., which may be readily achieved with resistor heating elements, provided that the overall print head is designed for a continuous operating temperature that corresponds to the melting point of the metal to be processed, or is slightly higher, for example 110% of the melting point. Heating wires or coils made of tungsten, for example, have a melting point of 3380° C., and therefore can easily withstand temperatures of 1000° C. For example, a ceramic material having sufficient heat resistance could be used as the material for the chassis of a print head.

In addition, it may be advantageous for this method when, prior to the actual printing operation, the metallized side of the carrier film is brought into close contact with the substrate to be imprinted, so that the thin metal layer is appropriately preheated. If necessary, this could be achieved using a pressure roller.

For this purpose, the substrate to be imprinted may optionally be transported through an oven beforehand. On the other hand, the surface to be imprinted could also be exposed to heat radiation, for example infrared radiation or microwave radiation.

The carrier film for the metal coating itself should be designed at least for the preheat temperature or for the sintering temperature of the metal, so that it does not lose its structural stability prior to the printing operation. Films made of polytetrafluoroethylene (Teflon) or smooth carbon films, or so-called ultrathin glass, would be suitable, depending on the metal being used.

Carbon films should be processed under a protective gas, since introduction of oxygen may result in softening of the carbon.

Ultrathin glass is a glass film having a thickness in a range of only 20 μm to 100 μm, typically approximately 50 μm. Such glass is very flexible due to its small thickness. It has the further advantage that it is transparent, and thus allows the heat radiation of a thermal print head to pass through unhindered. Quartz glasses having a high SiO₂ content, for example 70% by weight SiO₂ or greater, preferably 80% by weight SiO₂ or greater, in particular 90% by weight SiO₂ or greater, are thermally stable up to temperatures of 1500° C.

When such a film made of ultrathin glass having a high SiO₂ content is used, it is also possible to fuse silver onto a substrate without damaging the film. After the printing operation, the film is rewound, undamaged, onto a laydown spool.

Of course, it is also possible to operate at a maximum temperature below the sintering temperature. However, the individual metal particles then do not fuse together to form a combined matrix, and therefore transfer resistances remain at the contacts between adjacent metal particles. In this procedure, however, a low-melting adhesive film should then be used between the carrier film and the metal particles applied thereto, which disintegrates, i.e., melts or sublimes, under the influence of the thermal print head, and then releases the previously retained metal particles, which may then deposit on the substrate. Of course, the carrier film itself could also have a correspondingly low melting point. However, it would then have to be ensured that the film does not completely disintegrate, and remains at least in areas, and may thus be rewound, at least in part, onto the laydown spool.

In addition, the invention provides the option to imprint electrically nonconductive layers in the form of an electrically nonconductive printing medium onto the substrate, in particular under the influence of heat on the printing medium. It is thus possible to also seal the conductor tracks, using the same system.

For this purpose, it would be advisable to use a material having a relatively high melting point as the nonconductive layer, for example a film made of polytetrafluoroethylene (Teflon) or the above-mentioned ultrathin glass; however, it is preferred to use a type having a reduced SiO₂ content and thus a lower melting point that is within the processing range of the thermal printing device, i.e., preferably at or below the melting point of the metal applied therebeneath.

A second level may optionally be imprinted on a lowermost conductor track level that is sealed in this way, optionally using the same metal as in the first layer, or using a material having a lower melting point than the electrically nonconductive sealing layer.

An insulating layer may optionally once again be applied thereto, and if necessary, also further conductor track levels, each separated from one another in areas by nonconductive layers. However, it should be ensured that the melting points of newly imprinted layers are preferably not appreciably above the melting point of the layer situated therebeneath, or optionally are even at a lower temperature. When the melting temperatures are the same, melting through to lower layers may possibly be avoided by using short operating times.

In addition, electrical and/or electronic components such as resistors, voltage dividers, etc., may likewise be imprinted on the substrate by means of a resistive printing medium, and capacitors may be imprinted by providing, one on top of the other, a bottom layer made of an electrically conductive printing medium, a middle layer made of a nonconductive, for example dielectric, printing medium, and a top layer made of an electrically conductive printing medium, etc. Coils may likewise be imprinted as spiral coils, and optionally also components having other properties, such as hot or cold conductors, or also (electro)luminescent elements.

Laminated paper having an FR2 material code (FR stands for fire retardant) is suitable as a printed circuit board substrate. Mats, in particular glass fiber mats, having an FR4 material code and that are impregnated with a resin, for example epoxy resin, are also used. FR4 materials have better creep resistance and better high-frequency properties, as well as lower water absorption, than laminated paper.

In addition, a printed circuit board substrate having other materials as the base material is available for special applications. Mentioned in particular in this regard is Teflon, as well as aluminum oxide or ceramics, in particular in the form of low-temperature cofired ceramics (LTCC) and/or high-temperature cofired ceramics (HTCC), in particular also for applications in high-frequency technology. The above-mentioned materials are used to produce rigid printed circuit board substrates which thus have little or no flexibility.

In contrast, films, in particular polyester films, are suitable as flexible printed circuit board substrates.

Printed circuit board substrates subject to more stringent requirements regarding cooling or heat dissipation may have one or more cores made of a metal such as aluminum or copper, or made of a metal alloy.

According to the invention, the printing medium is provided in a two-dimensional layer of a thickness tₗ which varies only between a minimum thickness t_{l,min} and a maximum thickness t_{l.max}, where it applies:

$$( {t}_{l , max} - {t}_{l , min} ) / {t}_{l} \leq ε ,$$

with ε=0.2, or ε=0.1, or ε=0.05, or ε=0.02, or ε=0.01.

Further advantages are achieved, if the homogeneity of the thickness tₜ of the electrically conductive tracks applied onto the electrically nonconductive substrate is such that the thickness tₜ varies only between a minimum thickness t_{t,min} and a maximum thickness t_{t,max,} where it applies:

$$( {t}_{t , max} - {t}_{t , min} ) / {t}_{t} \leq ε ,$$

with ε=0.2, or ε=0.1, or ε=0.05, or ε=0.02, or ε=0.01.

On an electrically nonconductive substrate, the invention allows to establish electrically conductive tracks with a nominal thickness tₜ of 5 micrometers or more, for example with a nominal thickness tₜ of 10 micrometers or more, preferably with a nominal thickness tₜ of 20 micrometers or more, especially with a nominal thickness tₜ of 50 micrometers or more, especially with a nominal thickness tₜ of 100 micrometers or more.

The invention recommends that the foil-shaped carrier material is removed together with unused portions of the two-dimensional layer from the electrically nonconductive substrate, after the electrically conductive tracks have been applied on the electrically nonconductive substrate.

The invention can be further improved in that the foil-shaped carrier material is removed together with unused portions of the two-dimensional layer from the electrically nonconductive substrate by winding it on a laydown spool.

If, according to the teaching of the invention, the side of the carrier film bearing the printing medium is always oriented parallel to the substrate and rests flatly against the substrate in the whole area between the supply spool and the laydown spool, these two spools can be used to ensure a close contact between the electrically conductive printing medium on the one hand and the substrate to be imprinted on the other hand.

The invention recommends that axles or shafts of the supply spool and/or of the laydown spool can be adjusted in a direction perpendicular to the level of the substrate to be imprinted. Thereby, a close contact between the electrically conductive printing medium on the one hand and the substrate to be imprinted on the other hand can be realized even in case of an uneven substrate or in case of vibrations, etc.

A close contact between the electrically conductive printing medium on the one hand and the substrate to be imprinted on the other hand can be achieved by pressing the supply spool and/or the laydown spool against the substrate.

Furthermore, if the pressure between the electrically conductive printing medium on the one hand and the substrate to be imprinted on the other hand is strong enough in order to generate a friction between them, a synchronous transport between the vontacting elements can be assured.

If—as the invention recommends—the transport direction and transport speed of the carrier film bearing the printing medium is always equal to the transport direction and transport speed of the substrate, the transfer from the film-like carrier to the substrate can be done rather slowly, i.e. without any shortage of time.

The pressure between the supply spool and/or the laydown spool on the one hand and the substrate on the other hand can be generated by one or more springs.

Furthermore, at least in a section of the carrier film which is actually in the area of the print head, the moistening of the substrate by the melted and fluid printing medium can be assisted by pressing the carrier film and/or the printing medium against the substrate.

A first method for pressing the carrier film and/or the printing medium against the substrate comprises that, in a section of the carrier film which is actually in the area of the print head, a pressure roller is situated beneath a transport device for the substrate. If this roller presses the transport device, for example a conveyor belt, and the substrate supported thereby in a direction towards the carrier film and/or the printing medium, a close contact is guaranteed.

Another method for pressing the carrier film and/or the printing medium against the substrate is characterized in that, in a section of the carrier film which is actually in the area of the print head, a convexly curved surface is situated beneath a transport device for the substrate. Such a convexly curved surface has to be of only rather slight curvature, for example of a size which cannot be distincted from a flat plane by the naked eye. It only should be positioned in a height which raises the transport device and the substrate laying thereon for one or several millimeters above an exact plane connecting the contact lines of the supply spool and, respectively, of the laydown spool on the one hand and the substrate on the other hand.

The invention further relates to a device for manufacturing printed circuit boards for electrical and electronic circuits, comprising an electrically nonconductive substrate and electrically conductive tracks of homogenous thickness applied thereon, wherein the electrically conductive tracks are made of a material with a melting temperature higher than the melting temperature of soldering tin so that they will withstand the soldering of electronic components thereon by soldering tin without melting, which includes a device for providing a print medium comprising the material of the electrically conductive tracks as a two-dimensional layer above the electrically nonconductive substrate, and a print head for selectively heating the printing medium according to the desired conductor track layout, in order to transfer this printing medium onto the substrate, by a selective melting or sintering of the material for the electrically conductive tracks, wherein the print head does not come into direct contact with the printing medium, since at least a foil-shaped carrier material carrying the two-dimensional layer of the printing medium is situated between the print head and the two-dimensional layer of the printing medium.

This device includes on the one hand a device for providing a film that is coated with the printing medium, for example wound around a core, and unwinding this film, coated with the printing medium, at that location and placing it on or applying it to the substrate, and on the other hand includes a printing device in the form of a thermal print head having a plurality of independently heatable miniature elements, each of which heats a small area of the printing medium on the film, thus transferring the heated printing medium onto the electrically nonconductive substrate in order to produce a conductor track or the like at that location.

The electrically nonconductive substrate to be imprinted may preferably be transported past the printing device. The film-like carrier material with the printing medium initially planarly applied thereto may be transported at a comparable speed in parallel to the substrate to be imprinted, while the print head instead comes to a standstill or moves only transversely with respect to the transport direction. The planar carrier material is preferably unwound between two spools, i.e., from a supply spool onto a laydown spool, from or with which it may then be disposed of or recycled.

Multiple printing devices may be provided in succession in the transport direction of the substrate, each having a print head and a supply spool and laydown spool for a film with a specific printing medium, i.e., with an electrically conductive printing medium or with an electrically nonconductive printing medium, with a dielectric printing medium, or with an (electro) luminescent printing medium, etc.

By printing these various printing media above and beside one another, each printed circuit board having any desired conductor track layout may be manufactured by printing, optionally at the same time with various components such as coils, capacitors, resistors, etc. If discrete components such as transistors, microprocessors, or plug-in contacts are also necessary, soldering tags or soldering areas may likewise be imprinted for this purpose.

By use of the invention, more or less hard printed circuit boards are preferably imprinted, since with these printed circuit boards the imprinted conductor track structures are not subjected to appreciable bending stress, and therefore are not susceptible to wear.

According to the invention, the device for providing the printing medium is designed such that the thickness tₗ of the two-dimensional layer of the printing medium varies only between a minimum thickness t_{l,min} and a maximum thickness t_{l,max}, where it applies:

$$( {t}_{l , max} - {t}_{l , min} ) / {t}_{l} \leq ε ,$$

with ε=0.2, or ε=0.1, or ε=0.05, or ε=0.02, or ε=0.01.

Further advantages are achieved if the homogeneity of the thickness tₜ of the electrically conductive tracks applied onto the electrically nonconductive substrate is such that the thickness tₜ varies only between a minimum thickness t_{t,min} and a maximum thickness t_{t,max}, where it applies:

$$( {t}_{t , max} - {t}_{t , min} ) / {t}_{t} \leq ε ,$$

with ε=0.2, or ε=0.1, or ε=0.05, or ε=0.02, or ε=0.01.

The invention provides a device for removal of the foil-shaped carrier material together with unused portions of the two-dimensional layer from the electrically nonconductive substrate, after the electrically conductive tracks have been applied on the electrically nonconductive substrate.

The device for removal of the foil-shaped carrier material together with unused portions of the two-dimensional layer from the electrically nonconductive substrate can be in the shape of a laydown spool situated downstream of the print head, for winding the foil-shaped carrier material together with unused portions of the two-dimensional layer.

If, according to the teaching of the invention, the side of the carrier film bearing the printing medium is always oriented parallel to the substrate and rests flatly against the substrate in the whole area between the supply spool and the laydown spool, these two spools can be used to ensure a close contact between the electrically conductive printing medium on the one hand and the substrate to be imprinted on the other hand.

The invention recommends that axles or shafts of the supply spool and/or of the laydown spool should be adjustable in a direction perpendicular to the level of the substrate to be imprinted. By such feature, a close contact between the electrically conductive printing medium on the one hand and the substrate to be imprinted on the other hand can be realized even in case of an uneven substrate or in case of vibrations, etc.

A close contact between the electrically conductive printing medium on the one hand and the substrate to be imprinted on the other hand can be achieved by a device for pressing the supply spool and/or the laydown spool against the substrate.

The pressure between the supply spool and/or the laydown spool on the one hand and the substrate on the other hand can be generated by one or more springs.

Furthermore, if pressure exerted by one or more springs or the like between the electrically conductive printing medium on the one hand and the substrate to be imprinted on the other hand is strong enough in order to generate a friction between them, a synchronous transport between the vontacting elements can be assured.

If—as the invention recommends—the longitudinal axes of the supply spool and of the laydown spool are across the longitudinal axis of the direction of movement of the substrate, the transport direction and transport speed of the carrier film bearing the printing medium is always equal to the transport direction and transport speed of the substrate, the transfer from the film-like carrier to the substrate can be done rather slowly, i.e. without any shortage of time.

Furthermore, at least in a section of the carrier film which is actually in the area of the print head, the moistening of the substrate by the melted and fluid printing medium can be assisted by a device for pressing the carrier film and/or the printing medium against the substrate.

A first device for pressing the carrier film and/or the printing medium against the substrate can be designed in such a way that, in a section of the carrier film which is actually in the area of the print head, a pressure roller is situated beneath a transport device for the substrate. If this roller presses the transport device, for example a conveyor belt, and the substrate supported thereby in a direction towards the carrier film and/or the printing medium, a close contact is guaranteed.

Finally, another device for pressing the carrier film and/or the printing medium against the substrate may characterized in that, in a section of the carrier film which is actually in the area of the print head, a convexly curved surface is situated beneath a transport device for the substrate. Such a convexly curved surface has to be of only rather slight curvature, for example of a size which cannot be distincted from a flat plane by the naked eye. It only should be positioned in a height which raises the transport device and the substrate laying thereon for one or several millimeters above an exact plane connecting the contact lines of the supply spool and, respectively, of the laydown spool on the one hand and the substrate on the other hand.

### BRIEF DESCRIPTION OF THE DRAWINGS

Further features, particulars, advantages, and effects based on the invention result from the following description of one preferred embodiment of the invention, and with reference to the drawings, which show the following:

FIG. 1 shows a side view of a device according to the invention for manufacturing printed circuit boards for electrical and electronic circuits, including a thermal print head;

FIG. 2 shows a view of the bottom side of the thermal print head from FIG. 1, in the direction of the arrows II-II;

FIG. 3 shows another embodiment of a thermal print head in a view according to FIG. 1; and

FIG. 4 shows a printing system comprising multiple printing devices.

### DETAILED DESCRIPTION OF THE PREFERRED EMBODIMENTS

Within the scope of the invention, for manufacturing printed circuit boards for electrical and electronic circuits, a device 1 is used which has a print head 2 for selective, localized heating of individual print spots or pixels of an electrically conductive printing medium 3 that is present in planar form, so that the printing medium is sintered, fused on, or melted at the selected print spots or pixels, and after being transferred to a substrate 4 situated underneath or adjacently, the printing medium resolidifies there in the form of a combined matrix, resulting in the desired conductor tracks, in the ideal case without transfer resistances.

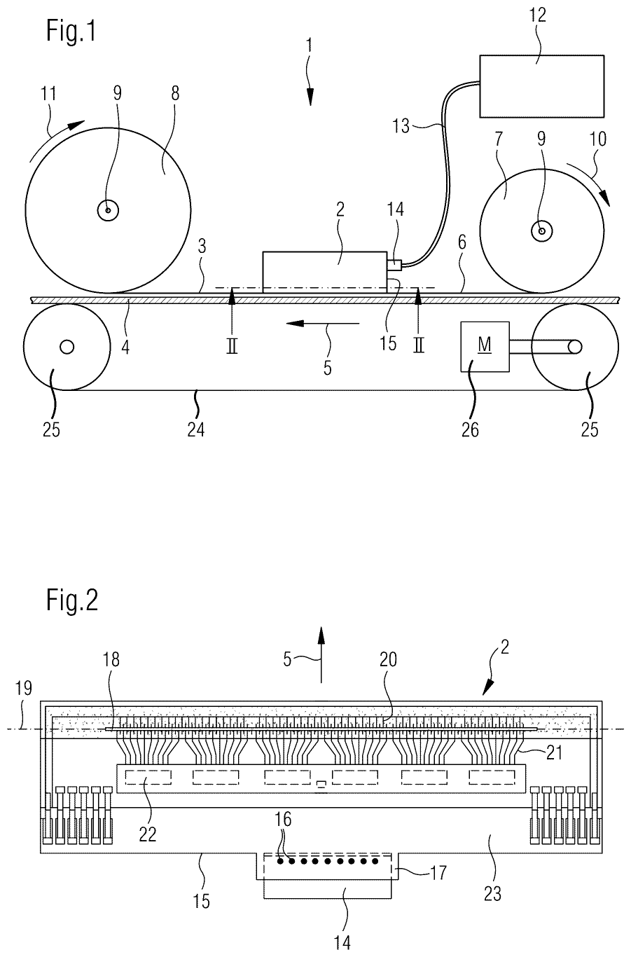

A transport device for setting the printed circuit board substrate 4 to be imprinted in motion 5 with respect to the print head 2 is not illustrated in FIG. 1. This may be a roller track or a conveyor belt, or also an oscillating plate.

In addition, a heating device may be situated in front of the print head, viewed in the transport direction 5, in order to preheat the printed circuit board substrate 4, thus reducing the heat that is to be generated by the thermal print head 2. This could be a thermal radiator along which the flat, in particular plate-shaped, substrate 4 is moved. On the other hand, it is also sufficient to preheat the printed circuit board material 4 in an oven, for example, from which it may then be removed, in a batchwise manner, for example, at the correct temperature.

The printing medium 3 is situated on the side or surface of a film-like carrier material 6 which faces the substrate 4, and which extends between the print head 2 and the substrate 4, at which location it may be transported synchronously with the transport movement 5.

The carrier material 6 preferably has the shape of a long strip that may be unwound from a supply spool 7 and a laydown spool 8.

With regard to the unwinding speed, it should also be ensured that it is preferably completely synchronous with the transport movement 5 of the substrate 4, so that preferably no relative movement occurs between the flat elements, namely, the substrate 4 on the one hand and the carrier material 6 on the other hand. This requires that, among other things, the supply spool 7 is situated upstream from the print head 2 with respect to the transport direction 5 of the substrate 4, while the laydown spool 8 is situated downstream from the print head 2.

The axles or shafts 9 of the supply spool 7 on the one hand and of the laydown spool 8 on the other hand may be adjustable in a direction perpendicular to the level of the substrate 4 to be imprinted, so that in the area of the print head 2 the section of the carrier film 6 bearing the printing medium 3 is always oriented parallel to the substrate 4, and preferably rests flatly against same.

When the supply spool and laydown spool 7, 8 are pressed against the substrate 4 in a frictionally locked manner, this frictional locking ensures that the peripheral speed 10, 11 of the supply spool and laydown spool 7, 8 is always equal to the transport speed 5 of the substrate 4, regardless of the instantaneous diameters of these two spools 7, 8, which in fact continuously change in the course of unwinding from the supply spool 7 to the laydown spool 8. Of course, such synchronicity between the spool peripheral speeds 10, 11 on the one hand and the transport speed 5 on the other hand could also be achieved by suitable control or regulation, which, however, means increased design complexity. In contrast to the first embodiment, where the supply spool and laydown spool 7, 8 are passively driven, i.e., their drive is received by the substrate 4 to be imprinted, in the latter case it would also be necessary to provide (separate) drives for the two spools 7, 8.

The print head 2 is controlled by a control device 12, preferably according to a conductor track layout stored therein. The control device 12 may be connected to the print head 2 via one or more preferably electrical control lines 13 that maintain contact with the print head 2 via a plug-in device 14, for example.

FIG. 2 illustrates one possible embodiment of the print head 2 in a more detailed view. A socket 17, provided with plug-in contacts 16, for inserting the plug 14 of the control device 12 is apparent on one side, for example on an upstream end-face side 15 of the print head 2.

The actual thermal heating device 18 of the print head 2 extends perpendicularly with respect to the transport direction 5 of the substrate 4, preferably along a straight line 19. This may be a linearly extending heating conductor 18 made of a very resistive material, for example tungsten, which is also the material of the heating wires in light bulbs.

A large number of feed lines 20, 21 branch off from this heating conductor 18, preferably in alternation in the transport direction 5 and opposite the transport direction.

Every other one of these feed lines 20, preferably the ones that branch off in the direction 5 opposite from the plug socket 17, are connected to one another and thus short-circuited, and are connected to a shared contact 16, preferably a ground contact at that location.

The remaining feed lines 21, which preferably branch off from the heating conductor 18 in the direction toward the plug socket 17, i.e., preferably opposite the transport direction 5, are each connected to a voltage supply, in particular to a contact pin 16 having a supply voltage, via a semiconductor switch 22.

The individual semiconductor switches 22 may be addressed via a line bus as a component of the feed line 13 and the corresponding plug-in contacts in order to selectively switch them on when the section of the heating conductor 18 associated with a semiconductor switch 22 is to be heated in order to print a pixel at the location in question.

The chassis 23 of the print head 2 is preferably made of ceramic or some other material that is suitable for high temperatures. The melting or softening temperature of this material should in particular be higher than the maximum operating temperature of the heating conductor 18.

In particular when the substrate 4 is preheated to a temperature just below the operating temperature of the heating conductor 18 by means of a heating device, not illustrated, or in an oven, only a small amount of energy needs to be supplied within the print head, so that, due to the additional quantity of heat, the temperature of the section of the heating wire 8 in question increases to the desired operating temperature.

Of course, it would also be possible in principle to use some other energy converter instead of a heating wire 18 to focus the necessary quantity of heat onto a spot of the substrate 4 to be imprinted. A comparatively large quantity of energy could be generated by means of a laser, for example, provided that the laser beam of the laser is guided to the spots in question, depending on the desired conductor track layout, and at that location is directed onto the carrier material 6 or preferably through same, directly into the printing medium 3.

This could take place, for example, by means of a plurality of optical fibers that are coupled on one end to the laser, and that on their other free end are each associated with a pixel or spot. Individual pixels or spots may be selectively heated by controlling, by means of light switches, the luminous flux between the laser and the optical fiber according to the desired conductor track layout.

An optimal energy yield or effectiveness is obtained when a laser in the red and/or infrared spectrum is used, so that the radiant power is delivered predominantly or exclusively as heat radiation.

In addition, so-called fiber lasers, a specialized form of solid-state lasers, appear to be particularly suitable. A doped core of a glass fiber is used as active medium, so that a fiber laser is thus a glass laser having properties of an optical fiber. The laser radiation is conducted by the laser-active fiber, and is highly intensified due to the comparatively long length.

Fiber lasers are generally optically pumped by coupling radiation of at least one diode laser in parallel to the fiber core, into the cladding of the fiber core or into the fiber core itself. A structure having so-called double-clad fibers delivers a higher power output; the pump radiation from the thick cladding passes into the active fiber core in a distributed manner.

Erbium, ytterbium, and/or neodymium may be used as doping elements for the laser-active fiber core. Usually only the middle portion of the glass fiber is doped.

Fiber lasers have electro-optical efficiencies of greater than 30%, as well as excellent beam quality, a long service life, and a compact, maintenance-free, robust design. In pulsed operation, fiber lasers may be used to achieve high peak intensities, and thus a high power density, to generate temperatures above the melting point T_{S} of metals such as silver (T_{S}=961° C.) or copper (T_{S}=1085° C.) at specific points. With this technique, it is thus possible to manufacture even continuous conductor tracks made of copper.

If necessary, multiple printing devices, each having one print head 2 and one supply spool and laydown spool 7, 8, may be situated in succession in the transport direction 5 of the strip-or film-like carrier material 6 in order to print multiple layers of electrically conductive and electrically nonconductive structures one on top of the other, or optionally also structures made of specialized materials such as dielectrics, for example for manufacturing a film capacitor. However, for layers that are to be printed one on top of the other, it should be ensured that structures that are already applied are not remelted, which could result in undesirable short circuits between various layers. Therefore, it is recommended to limit the number of layers that are to be printed one on top of the other, and preferably to laminate multiple substrate layers 4 onto one another which have already been appropriately imprinted in each case.

Furthermore, FIG. 1 shows a transport device 24 for moving the substrate 4 relative to the print head 2 in the direction of the movement 5. The transport device 24 may have the form of an endless conveyor belt which is spanned over two rollers 25, one of which is driven by a motor 26.

The velocity of the movement 5 which is imparted to the substrate 4 by the transport device 24 shall be the same as the velocity of the movement of the printing medium 3 on the foil-shaped carrier material 6.

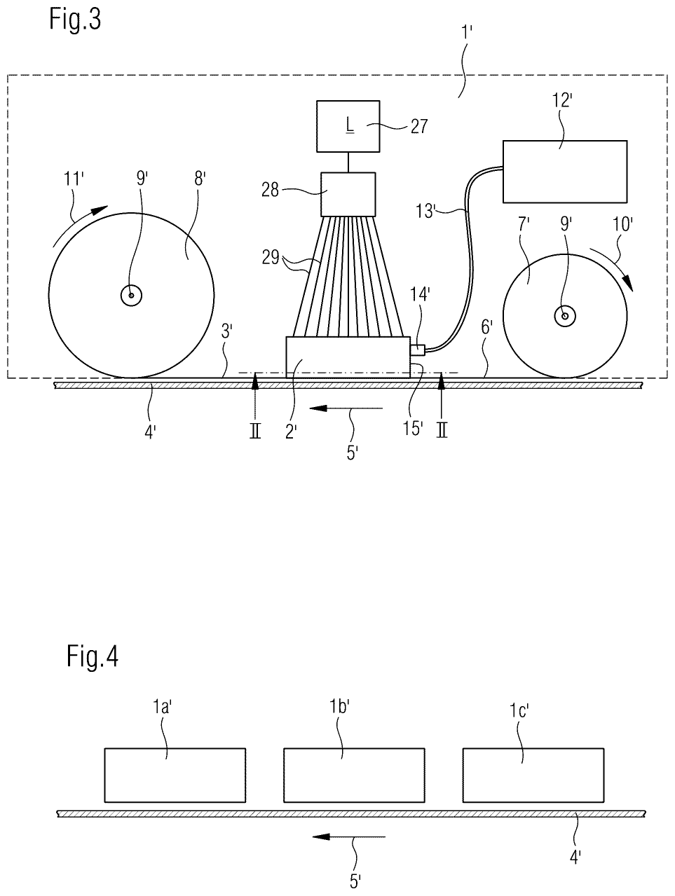

FIG. 3 shows another embodiment of the invention where the print head 2 comprises at least one heating device in the form of a laser 27, and a number of individual optical fiber sections 29 which in each case end at different spots and may be selectively excited with the beam of the laser 27 under control of a selector 28 in order to induce heat at a spot and thus print a pixel at that location.

FIG. 4 shows a printing system with multiple printing devices 1a′, 1b′, 1c′, each having one thermal print head 2′ and one supply spool and laydown spool 7′, 8′ for each strip-or film-like carrier material 6′ provided with the printing medium 3′, the printing devices being situated in succession in the transport direction 5′ of the substrate 4′ to be imprinted.

It is to be noted that some or all of the multiple printing devices 1a′, 1b′, 1c′ may be embodied like the printing device 1 of FIG. 1, of course.

List of reference numerals

| | |
|---|---|
| 1 | device |
| 2 | print head |
| 3 | printing medium |
| 4 | substrate |
| 5 | transport movement |
| 6 | carrier material |
| 7 | supply spool |
| 8 | laydown spool |
| 9 | axle, shaft |
| 10 | peripheral speed |
| 11 | peripheral speed |
| 12 | control device |
| 13 | control line |
| 14 | plug-in-device |
| 15 | upstream end-face side |
| 16 | plug-in contacts |
| 17 | socket |
| 18 | heating conductor |
| 19 | straight line |
| 20 | feed line |
| 21 | feed line |
| 22 | semiconductor switch |
| 23 | chassis |
| 24 | transport device |
| 25 | roller |
| 26 | drive motor |
| 27 | laser |
| 28 | selector |
| 29 | optical fibers |

What is claimed is:

1. A method for manufacturing printed circuit boards for electrical and electronic circuits, comprising an electrically nonconductive substrate (4) and electrically conductive tracks applied thereon, wherein the electrically conductive tracks are imprinted on the substrate (4), according to a desired conductor track layout, under the influence of heat applied to an electrically conductive printing medium (3), wherein the printing medium (3) comprises an electrically conductive metal or metal alloy having a melting temperature, and wherein the metal or metal alloy is configured to be selectively heated by a print head (2) at selected printing spots or pixels, wherein a conductive ingredient of the metal or metal alloy of the printing medium (3)
is locally heated at least up to the melting temperature of the metal or the metal alloy, which is the melting point of the metal or metal alloy in the form of a bulk material and is melted thereby, and
thereafter solidifys on the substrate (4) in the form of a common matrix,
and wherein the printing medium (3) is situated on a side of-a film-like carrier (6), which side of the film-like carrier (6) faces the substrate (4), characterized in that the film-like carrier (6)
is a carbon foil or a glass film, and
is wound from a supply spool (7), along the substrate (4) to be imprinted, onto a laydown spool (8), and
wherein, at least in a section of the carrier film (6) which is actually in the area of the print head (2), the side of the carrier film (6) bearing the printing medium (3) is always oriented parallel to the substrate (4) and rests flatly against the substrate (4), so that the metal or metal alloy is in direct contact with the substrate (4), and, after being melted by the print head (2) into its fluid aggregate state, the metal or metal alloy immediately moistens the substrate (4) and finally solidifies on the substrate (4) as a common matrix.

2. The method according to claim 1, characterized in that the electrically conductive printing medium (3) is heated by means of a thermal print head (2).

3. The method according to claim 1, characterized in that at least one electrically nonconductive layer in the form of an electrically nonconductive printing medium (3) is imprinted on the substrate (4).

4. The method according to claim 1, characterized in that electrical or electronic components are likewise imprinted on the substrate (4).

5. A device (1) for manufacturing printed circuit boards for electrical and electronic circuits, comprising an electrically nonconductive substrate (4) and electrically conductive tracks applied thereon, the device comprising:
a supply spool (7) with a foil-like carrier, wherein an electrically conductive printing medium (3) is applied to the foil-like carrier (6), and wherein the foil-like carrier (6) can be wound from supply spool (7), along a substrate (4) to be imprinted, onto a laydown spool (8), and
a print head (2) for selectively heating an electrically conductive printing medium (3) according to the desired conductor track layout, in order to transfer this printing medium (3) onto the substrate (4), wherein the printing medium (3) comprises as electrically conductive ingredient a metal or a metal alloy, which has a melting temperature typical for the metal or the metal alloy and can be heated selectively by a printing head (2) at selected printing spots or pixels,
wherein the print head (2) is formed in such a way that the metallic, conducting ingredient of the printing medium (3)
is locally heated up to the typical melting temperature of the metal or the metal alloy and is melted thereby, and
solidifys on the substrate (4) in the form of a common matrix,
wherein the foil-like carrier is a carbon foil or a glass film, and wherein, at least in a section of the carrier film (6) which is actually in the area of the print head (2), the carrier film (6) is guided such that the side of the carrier film (6) bearing the printing medium (3) is always oriented parallel to the substrate (4) and rests flatly against the substrate (4), so that the metal or metal alloy is in direct contact with the substrate (4), and, after being melted by the print head (2) into its fluid aggregate state, the metal or metal alloy immediately moistens the substrate (4) and finally solidifies on the substrate (4) as a common matrix.

6. The device (1) according to claim 5, characterized in that the print head (2) has at least one heating device, preferably a heating conductor (18) having a fairly large number of individual sections that can be selectively supplied with current or voltage in order to induce heat at the spot in question and thus print a pixel at that location.

7. The device (1) according to claim 5, characterized in that the print head (2) has at least one heating device, preferably a laser, having a fairly large number of individual optical fiber sections which in each case end at different spots and may be selectively excited with the beam of the laser in order to induce heat at the spot in question and thus print a pixel at that location.

8. The device (1) according to claim 5, characterized by a transport device for moving the substrate (4) relative to the print head (2) (movement (5)).

9. The device (1) according to claim 8, characterized in that the printing medium (3) is applied to a film-like carrier (6) that is unwound from a supply spool (7), along the substrate (4) to be imprinted, onto a laydown spool (8).

10. The device (1) according to claim 8, characterized in that the transport speed of the film-like carrier (6) in the area between the supply spool (7) and the laydown spool (8) is equal to the transport speed (5) of the substrate (4) to be imprinted.

11. The device (1) according to claim 5, characterized by multiple printing devices, each having a thermal print head (2) and a supply spool as well as a laydown spool (7, 8) for a strip-or film-like carrier material (6) each provided with a printing medium (3), the printing devices being arranged in succession in the transport direction (5) of the substrate (4) to be imprinted.

12. The device (1) according to claim 5, characterized by a thermal print head (2) for selectively heating an electrically conductive printing medium (3) according to a desired conductor track layout, in order to transfer this printing medium (3) onto the substrate (4), wherein the thermal print head (2) does not come into direct contact with the electrically conductive printing medium (3) to be printed, since a carrier material carrying the electrically conductive printing medium (3) is still situated in between.

13. The device (1) according to claim 5, characterized by a print head (2) for selectively heating an electrically conductive printing medium (3) comprising particles of a metal or metal alloy with a melting point of 1.500° C. or less to a temperature of at least 80% of the melting point of the regarding metal or metal alloy, according to a desired conductor track layout, in order to transfer this printing medium (3) onto the substrate (4), wherein the particles of a metal or metal alloy are sintered or melted together, and wherein the print head (2) does not come into direct contact with the electrically conductive printing medium (3) to be printed, since a carrier material carrying the electrically conductive printing medium (3) is still situated in between.

14. The device (1) according to claim 5, characterized in that the device for providing the printing medium (3) is designed such that the thickness (tₗ) of the two-dimensional layer of the printing medium (3) varies only between a minimum thickness (t_{l,min}) and a maximum thickness (t_{l,max}), where it applies:
$$( {t}_{l , max} - {t}_{l , min} ) / {t}_{l} \leq ε ,$$
with ε=0.2, or ε=0.1, or ε=0.05, or ε=0.02, or ε=0.01.

15. The device (1) according to claim 5, characterized in that the homogeneity of the thickness (tₜ) of the electrically conductive tracks applied onto the electrically nonconductive substrate (4) is such that the thickness (tₜ) varies only between a minimum thickness (t_{t,min}) and a maximum thickness (t_{t,max}), where it applies:
$$( {t}_{t , max} - {t}_{t , min} ) / {t}_{t} \leq ε ,$$
with ε=0.2, or ε=0.1, or ε=0.05, or ε=0.02, or ε=0.01.

16. The device (1) according to claim 5, characterized by a device for removal of the foil-shaped carrier material together with unused portions of the two-dimensional layer from the electrically nonconductive substrate (4), after the electrically conductive tracks have been applied on the electrically nonconductive substrate (4).

17. The device (1) according to claim 16, characterized in that the device for removal of the foil-shaped carrier material together with unused portions of the two-dimensional layer from the electrically nonconductive substrate (4) is in the shape of a laydown spool (8) situated downstream of the print head (2), for winding the foil-shaped carrier material together with unused portions of the two-dimensional layer.

18. The method according to claim 1, characterized in that the printing medium (3) is provided in a two-dimensional layer of a thickness (tₗ) which varies only between a minimum thickness (t_{l,min}) and a maximum thickness (t_{l,max)}, where it applies:
$$( {t}_{l , max} - {t}_{l , min} ) / {t}_{l} \leq ε ,$$
with ε=0.2, or ε=0.1, or ε=0.05, or ε=0.02, or ε=0.01.

19. The method according to claim 1, characterized in that the homogeneity of the thickness (tₜ) of the electrically conductive tracks applied onto the electrically nonconductive substrate (4) is such that the thickness (tₜ) varies only between a minimum thickness (t_{t,min}) and a maximum thickness (t_{t,max}), where it applies:
$$( {t}_{t , max} - {t}_{t , min} ) / {t}_{t} \leq ε ,$$
with ε=0.2, or ε=0.1, or ε=0.05, or ε=0.02, or ε=0.01.

20. The method according to claim 1, characterized in that the foil-shaped carrier material is removed together with unused portions of the two-dimensional layer from the electrically nonconductive substrate (4), after the electrically conductive tracks have been applied on the electrically nonconductive substrate (4).

21. The method according to claim 20, characterized in that the foil-shaped carrier material is removed together with unused portions of the two-dimensional layer from the electrically nonconductive substrate (4) by winding it on a laydown spool (8).

22. The method according to claim 3, characterized in that at least one electrically nonconductive layer in the form of an electrically nonconductive printing medium (3) is imprinted on the substrate (4) under the influence of heat on the printing medium (3).

23. The method according to claim 4, characterized in that resistors and/or voltage dividers as electrical or electronic components are likewise imprinted on the substrate (4) by means of a resistive printing medium (3).

24. The method according to claim 4, characterized in that capacitors as electrical or electronic components are likewise imprinted on the substrate (4) by providing, one on top of the other, a bottom layer made of an electrically conductive printing medium (3), a middle layer made of a nonconductive printing medium (3), and a top layer made of an electrically conductive printing medium (3).

25. The method according to claim 1, characterized in that the side of the carrier film (6) bearing the printing medium (3) is always oriented parallel to the substrate (4) and rests flatly against the substrate (4) in the whole area between the supply spool (7) and the laydown spool (8).

26. The method according to claim 1, characterized in that axles or shafts (9) of the supply spool (7) and/or of the laydown spool (8) is (are) adjustable in a direction perpendicular to the level of the substrate (4) to be imprinted.

27. The method according to claim 1, characterized in that the supply spool (7) and/or the laydown spool (8) is (are) pressed against the substrate (4) in a frictionally locked manner.

28. The method according to claim 1, characterized in that the supply spool (7) and/or the laydown spool (8) is (are) pressed against the substrate (4) by one or more springs.

29. The method according to claim 1, characterized in that, at least in a section of the carrier film (6) which is actually in the area of the print head (2), the transport direction and transport speed of the carrier film (6) bearing the printing medium (3) is always equal to the transport direction and transport speed (5) of the substrate.

30. The method according to claim 1, characterized in that, at least in a section of the carrier film (6) which is actually in the area of the print head (2), the moistening of the substrate (4) by the melted and fluid printing medium (3) is assisted by pressing the carrier film (6) and/or the printing medium (3) against the substrate.

31. The method according to claim 30, characterized in that, in a section of the carrier film (6) which is actually in the area of the print head (2), a pressure roller is situated beneath a transport device (24) for the substrate (4).

32. The method according to claim 30, characterized in that, in a section of the carrier film (6) which is actually in the area of the print head (2), a convexly curved surface is situated beneath a transport device (24) for the substrate (4).

33. The device according to claim 5, characterized in that the side of the carrier film (6) bearing the printing medium (3) is always oriented parallel to the substrate (4) and rests flatly against the substrate (4) in the whole area between the supply spool (7) and the laydown spool (8).

34. The device according to claim 5, characterized in that axles or shafts (9) of the supply spool (7) and/or of the laydown spool (8) is (are) adjustable in a direction perpendicular to the level of the substrate (4) to be imprinted.

35. The device according to claim 5, characterized in that the supply spool (7) and/or the laydown spool (8) is (are) pressed against the substrate (4) in a frictionally locked manner.

36. The device according to claim 5, characterized in that the supply spool (7) and/or the laydown spool (8) is (are) pressed against the substrate (4) by one or more springs.

37. The device according to claim 5, characterized in that, at least in a section of the carrier film (6) which is actually in the area of the print head (2), the transport direction and transport speed of the carrier film (6) bearing the printing medium (3) is always equal to the transport direction and transport speed (5) of the substrate.

38. The device according to claim 5, characterized in that, at least in a section of the carrier film (6) which is actually in the area of the print head (2), the moistening of the substrate (4) by the melted and fluid printing medium (3) is assisted by pressing the carrier film (6) and/or the printing medium (3) against the substrate.

39. The device according to claim 5, characterized in that, in a section of the carrier film (6) which is actually in the area of the print head (2), a pressure roller is situated beneath a transport device (24) for the substrate (4).

40. The device according to claim 5, characterized in that, in a section of the carrier film (6) which is actually in the area of the print head (2), a convexly curved surface is situated beneath a transport device (24) for the substrate (4).
